(19) United States
(12) Patent Application Publication
(10) Pub. No.: US 2006/0289847 A1
(43) Pub. Date: Dec. 28, 2006

(54) Reducing the time to program a phase change memory to the set state

(76) Inventor: Richard Dodge, Santa Clara, CA (US)

Correspondence Address: TROP PRUNER & HU, PC, 1616 S. VOSS ROAD, SUITE 750, HOUSTON, TX, 77057-2631, US

(21) Appl. No.: 11/168,783

(22) Filed: Jun. 28, 2005

(51) Int. Cl. H01L 29/02; H01L 21/76

(52) U.S. Cl. 257/2; 257/4; 257/5; 438/409

(57) ABSTRACT

A phase change memory may be formed with a chalcogenide layer that contains titanium. The titanium reduces the crystallization time. Set state resistance may also be decreased, thereby reducing the access time of the semiconductor memory, in some embodiments.

### BACKGROUND

This invention relates generally to semiconductor memories using chalcogenide.

Phase change memory devices use phase change materials, i.e., materials that may be electrically switched between a generally amorphous and a generally crystalline state, for electronic memory application. One type of memory element utilizes a phase change material that may be, in one application, electrically switched between a generally amorphous structural state and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is a greatly enlarged, cross-sectional view at an early stage of manufacture;

FIG. 2 is a greatly enlarged, cross-sectional view of the embodiment shown in FIG. 1 at a later stage in accordance with one embodiment of the present invention;

FIG. 3 is a greatly enlarged, cross-sectional view of the embodiment shown in FIG. 2 at a later stage in accordance with one embodiment of the present invention;

FIG. 4 is a schematic depiction of a sputter deposition apparatus in accordance with one embodiment of the present invention;

FIG. 5 is a greatly enlarged, cross-sectional view of the completed memory in accordance with one embodiment of the present invention; and

FIG. 6 is a system depiction in accordance with one embodiment of the present invention.

### DETAILED DESCRIPTION

A write operation in chalcogenide containing phase change memory may include both setting a bit and resetting a bit. Resetting is typically much faster than setting the bit. The reset state may be a more amorphous state and the set state may be a more crystalline state. By reducing the time required for crystallization, the time to transition from the reset to the set state is reduced and the write cycle time may be significantly reduced. In addition, access time may be improved by reducing the set state resistance, in some embodiments.

Thus, a controllable technique may be used to reduce the recrystallization time to increase the speed of writing a set bit, and obtaining a lower set resistance, in some embodiments. A material may be added to the chalcogenide alloy in order to reduce the crystallization time. By “controllable technique,” it is intended to refer to a technique which allows a determination of the amount of the material that is added to the chalcogenide to reduce its crystallization time.

A material that reduces the crystallization time is titanium. Thus, in some embodiments, a chalcogenide material, which is transformed between the set and reset states, is doped with titanium to reduce its crystallization time. Generally, a very small amount of titanium material is added to the chalcogenide. For example, in some embodiments, the percentage by weight of titanium to chalcogenide may be less than 5 percent. Any of a variety of useful chalcogenide materials may be utilized, including the so-called 225 GST chalcogenide which is Ge₂Sb₂Te₅.

While any of a variety of architectures and techniques may be utilized to manufacture phase change semiconductor memories, including a crystallization reducing material in the chalcogenide, an example is given in the following discussion which should not limit the scope of the present invention. While only a single cell of a memory is illustrated, cells may be arranged in large numbers in rows and columns in some embodiments.

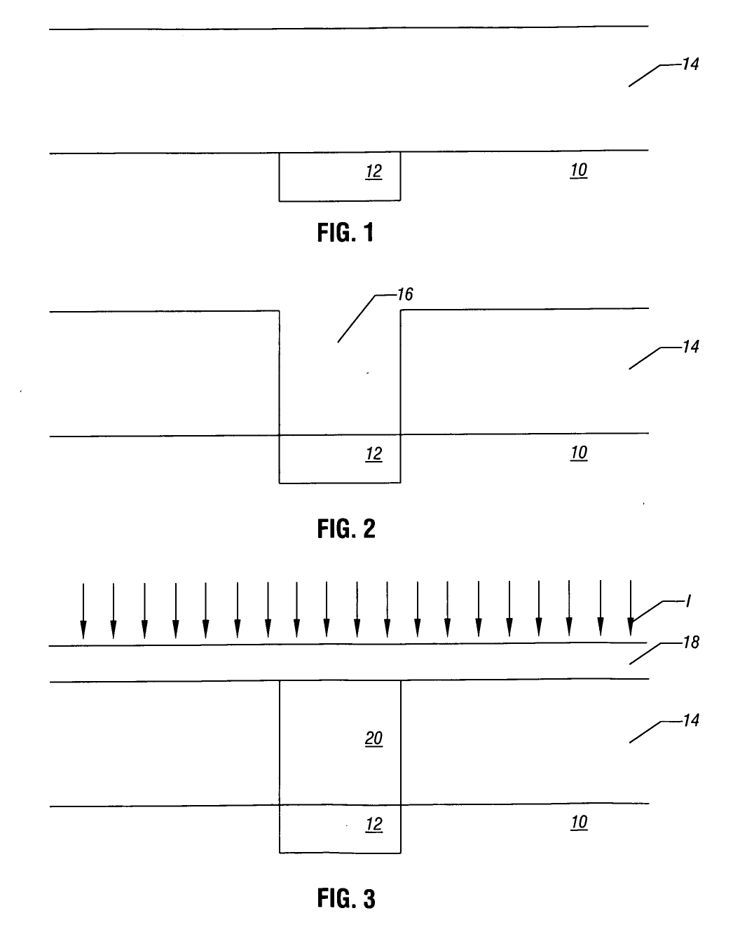

Referring to FIG. 1, a first conductive line 12 may be formed in a structure 10. The structure 10 may be an interlayer dielectric over a semiconductor substrate. The line 12 may, for example, be a row line. The line 12 may be formed of any of a variety of conductors, including copper. An insulating layer 14, such as an oxide layer, may then be formed over the substrate 10.

As shown in FIG. 2, a pore 16 may be formed in the insulating layer 14 using any of a variety of techniques. Thereafter, the pore 16 may be filled with a heater 20 in accordance with one embodiment of the present invention. The heater 20 may be any of a variety of resistive, conductive materials, including titanium nitride. Then, a chalcogenide layer 18 may be formed over the insulating layer 14.

The chalcogenide layer 18 may be substantially planar in one embodiment, although many other configurations are also contemplated. However, one advantage of a planar chalcogenide layer 18, in some embodiments, is that it is easier to add a crystallization time reducing material, such as titanium, to the layer 18 after the layer has already been formed. For example, as illustrated in FIG. 3, an exposure I of the crystallization time reducing material may be readily implemented. The exposure I may, for example, be an ion implantation of titanium. The ion implantation may be followed by an anneal.

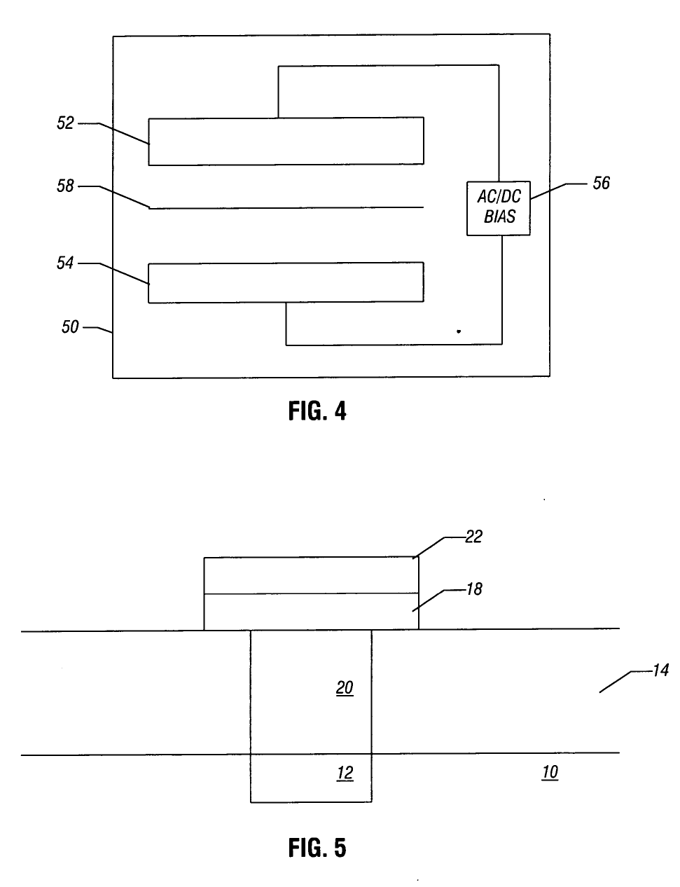

In another embodiment, a sputter deposition process, illustrated in FIG. 4, may be utilized to deposit the chalcogenide layer 18. In sputter deposition, an alternating current or direct current bias 56 is applied between the substrate 52 and a target 54. A shutter 58 may be provided between the substrate 52 and the target 54. The structure is enclosed within a sputter deposition housing 50. The substrate 52 may be the structure shown in FIG. 3.

The target 54 may be formed of powders of the materials that will form the layer 18. For example, the powders may include germanium, antimony, and tellurium, as well as the crystallization time reducing material, titanium. These powders may be pressed together to form the target 54. Then, when a bias is applied, such as a radio frequency alternating current bias, the target ejects its material which is then deposited as a mixture on the substrate 52. As a result, the substrate 52 may be coated with a layer 18 which includes a chalcogenide such as 225 GST, doped with titanium. In such case, the titanium is thoroughly and uniformly dispersed throughout the layer 18.

A controllable process may be utilized wherein the crystallization time may be precisely reduced as desired. In connection with an ion implantation process, the time, energy, and dose may be set to determine how much titanium is added to the chalcogenide layer 18. In connection with a sputter deposition process, the relative amounts of powders used to form the target may be precisely controlled. Conversely, a diffusion process is dependent on thermal budget and is not a “controllable technique” as used herein.

After the chalcogenide layer 18 has been controllably doped with crystallization time reducing material, an upper electrode 22 may be deposited and, then, in some embodiments, the upper electrode 22 and chalcogenide layer 18 may be patterned and etched to form stripes or dots, as indicated in FIG. 5.

The chalcogenide layer 18 may be a phase change, programmable material capable of being programmed into one of at least two memory states by applying a current to alter the phase of memory material between a more crystalline state and a more amorphous state, wherein the resistance of memory material in the substantially amorphous state is greater than the resistance of memory material in the substantially crystalline state.

Programming of the layer 18 to alter the state or phase of the material may be accomplished by applying voltage potentials to electrodes or lines 12 and 22, thereby generating a voltage potential across the layer 18. An electrical current may flow through the layer 18 in response to the applied voltage potentials, and may result in heating of the layer 18. For example, in one embodiment, a pulse on the order of 10 nanoseconds may be used to program the material to the reset state.

This heating may alter the state or phase of chalcogenide. Altering the phase or state of layer 18 may alter the electrical characteristic of memory material, e.g., the resistance of the material may be altered by altering the phase of the memory material.

In the “reset” state, memory material may be in an amorphous or semi-amorphous state and in the “set” state, memory material may be in a crystalline or semi-crystalline state. The resistance of memory material in the amorphous or semi-amorphous state may be greater than the resistance of memory material in the crystalline or semi-crystalline state. It is to be appreciated that the association of “reset” and “set” with amorphous and crystalline states, respectively, is a convention and that at least an opposite convention may be adopted.

Using electrical current, the memory material may be heated to a relatively higher temperature to amorphosize memory material and “reset” memory material (e.g., program memory material to a logic “0” value). Heating the volume of memory material to a relatively lower crystallization temperature may crystallize memory material and “set”memory material (e.g., program memory material to a logic “1” value). Various resistances of memory material may be achieved to store information by varying the amount of current flow and duration through the volume of memory material.

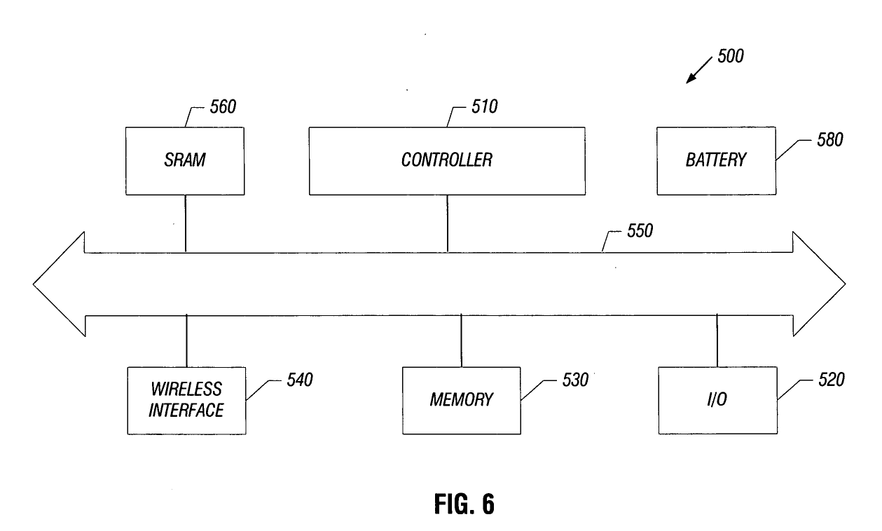

Turning to FIG. 6, a portion of a system 500, in accordance with an embodiment of the present invention, is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), a memory 530, and a wireless interface 540 coupled to each other via a bus 550. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect. A static random access memory (SRAM) 560 may also be coupled to bus 550.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
using a controllable technique to form a semiconductor phase change memory with a titanium containing chalcogenide layer.

2. The method of claim 1 including doping the chalcogenide layer with titanium using ion implantation.

3. The method of claim 1 including forming a target containing titanium and chalcogenide materials and using sputtering to deposit chalcogenide containing titanium.

4. The method of claim 1 including forming a chalcogenide layer containing 225 GST and titanium.

5. The method of claim 1 including reducing the crystallization time of the chalcogenide layer using titanium.

6. A method comprising:
reducing the set state resistance of a semiconductor phase change memory using titanium.

7. The method of claim 6 including forming a chalcogenide containing layer containing titanium.

8. The method of claim 6 including doping the chalcogenide containing layer using a titanium ion implantation.

9. The method of claim 6 including forming a target containing titanium and chalcogenide and using sputter deposition to form a titanium containing chalcogenide layer.

10. A target for a sputter deposition chamber comprising:
titanium and a chalcogenide material.

11. The target of claim 10 wherein said target includes less than 5 percent titanium by weight.

12. The target of claim 10 wherein the chalcogenide includes germanium, antimony, and tellurium.

13. A phase change memory comprising:
a layer of chalcogenide having ion implanted titanium.

14. The memory of claim 13 wherein titanium is less than 5 percent by weight of the chalcogenide.

15. The memory of claim 13 wherein said chalcogenide includes 225 GST.

16. A phase change memory comprising:
a layer of chalcogenide having titanium uniformly distributed throughout said chalcogenide.

17. The memory of claim 16 wherein said titanium is less than 5 percent by weight of the chalcogenide.

18. The memory of claim 16 wherein said chalcogenide includes germanium, antimony, and tellurium.

19. The memory of claim 16 including a pair of electrodes sandwiching said chalcogenide.

20. The memory of claim 16 wherein said chalcogenide is sputter deposited chalcogenide.

21. A system comprising:
a controller;
a static random access memory coupled to said controller; and
a semiconductor phase change memory, coupled to said controller, including chalcogenide having titanium uniformly dispersed throughout the chalcogenide.

22. The system of claim 21 wherein said titanium is less than 5 percent by weight of said chalcogenide.

23. The system of claim 21 wherein said chalcogenide includes 225 GST.

24. The system of claim 21 including a pair of electrodes sandwiching said chalcogenide.

25. The system of claim 21 wherein said chalcogenide is sputter deposited chalcogenide.
